(19) United States
(12) Patent Application Publication
(10) Pub. No.: US 2016/0163887 A1
(43) Pub. Date: Jun. 9, 2016

(54) SILICON SUBSTRATE FOR SOLAR CELL AND MANUFACTURING METHOD THEREFOR

(71) Applicant: KOREA INSTITUTE OF INDUSTRIAL TECHNOLOGY, Chungcheongnam-do (KR)

(72) Inventors: Chae Hwan JEONG, Gwangju (KR); Sung Jae PARK, Gwangju (KR); Ho Sung KIM, Gwangju (KR)

(73) Assignee: KOREA INSTITUTE OF INDUSTRIAL TECHNOLOGY, Cheonan-si, Chungcheongnam-do (KR)

(21) Appl. No.: 14/908,461

(22) PCT Filed: Jun. 3, 2014
(86) PCT No.: PCT/KR2014/004920

§ 371 Date: Jan. 28, 2016

(30) Foreign Application Priority Data
Jul. 29, 2013 (KR) 10-2013-0089229

(51) Int. Cl. H01L 31/0236; H01L 31/18; H01L 31/0216; H01L 31/028

(52) U.S. Cl. CPC H01L 31/02363; H01L 31/0284; H01L 31/1804; H01L 31/02168

(57) ABSTRACT

Disclosed are a silicon substrate for a solar cell and a method of manufacturing the same, wherein the reflectance of solar light can be decreased by gap-filling with AZO, and electrical properties, especially resistivity, can be reduced through e-beam irradiation, thus maximizing the cell efficiency and improving the electrical properties of AZO applied to a silicon solar cell.

### TECHNICAL FIELD

The present invention relates to a silicon substrate for a solar cell and a method of manufacturing the same and, more particularly, to a silicon substrate for a solar cell and a method of manufacturing the same, wherein the reflectance of solar light may be decreased by gap-filling with AZO (Al-doped ZnO), and electrical properties, especially resistivity, may be reduced through irradiation with an e-beam, thus maximizing the cell efficiency and improving the electrical properties of AZO applied to a silicon solar cell.

### BACKGROUND ART

With the current increase in greenhouse gas emission reduction obligations through conventions on climate change, carbon dioxide markets have become activated, and thus new renewable energy is receiving attention.

Examples of new renewable energy may include solar light, wind power, biomass, geothermal power, water power, tidal power, etc. In particular, a solar cell is a system for producing electricity using solar light, which is an infinite clean energy source, the rapid growth of which is expected, and such a solar cell functions to directly convert light into electricity.

Also, solar cells are the only power source that decreases power generation costs, and adopt the energy that obviates the construction of power plants, incurs only maintenance costs, and is safe and environmentally friendly, unlike nuclear energy.

A variety of kinds of solar cells are provided, which include typical crystalline solar cells, CIGS as thin-film-type solar cells, and DSSC as next-generation solar cells.

A silicon thin-film solar cell includes an amorphous silicon (a-Si:H) solar cell, which was first developed and distributed, and a microcrystalline silicon (μc-Si:H) solar cell for increasing light absorption efficiency.

A substrate for a solar cell is configured such that a p-type semiconductor and an n-type semiconductor are provided on respective sides of a very thin layer comprising a semiconductor monocrystal. In this case, a p-n junction is formed at the region where anode and cathode semiconductors are in contact with each other, that is, a region where a p-type semiconductor is in contact with an n-type semiconductor, and positive voltage and negative voltage are respectively applied to a p-type portion and an n-type portion, whereby current flows. Furthermore, specific properties such as rectification of the p-n junction at the interface thereof may be utilized in many semiconductor devices, such as diodes or transistors.

In the use of solar cells to date, indium tin oxide (ITO), configured such that a trace amount of tin (Sn), having superior electrical resistivity and high transmittance, is contained in indium oxide (In₂O₃), has been mainly used in the form of a thin film as a transparent conductive oxide (TOO). However, since the indium material is very expensive and reserves thereof are limited, a ZnO-based thin film, which has low material cost, high transmittance in the IR and visible light ranges, high electrical conductivity and superior plasma durability, is being used to replace the ITO transparent conductive thin film. However, when the ZnO-based thin film is exposed to air for a long period of time, the electrical properties thereof may change due to the effect of oxygen, and it is not stable in high-temperature atmospheres. Hence, in order to alleviate such defects, there has been recently introduced an Al-doped ZnO (AZO) thin film configured such that ZnO, having high light transmittance in the visible light range, comparatively low electrical resistivity, and high chemical stability to hydrogen plasma, is doped with a small amount of Al.

Typically, the visible light transmittance and electrical resistance of a transparent electrode material such as AZO vary depending on the film-forming conditions, including deposition equipment, substrate temperature, etc. The transparent electrode using AZO is manufactured through chemical vapor deposition, DC and RF sputtering, activated reactive evaporation (ARE) or the like. Although RF sputtering is known to be an optimal deposition process for realizing high electrical conductivity, there are no systematic reports for the optimal formation conditions thereof.

In a silicon solar cell in particular, a great amount of light has to be absorbed into silicon of the solar cell. Although silicon may be advantageously easily obtained compared to cadmium or telluride, which is a material for a high-efficiency thin-film solar cell, it has a relatively high refractive index, and thus 20 to 30% of incident light is undesirably reflected again without producing electric charges. The reflection of light is known to be decreased through an anti-reflective layer or a texturing process, but methods of more efficiently decreasing the reflection of light from the surface of the solar cell are still required.

### DISCLOSURE

### Technical Problem

Accordingly, the present invention has been made keeping in mind the above problems occurring in the related art, and an object of the present invention is to provide a method of manufacturing a silicon substrate for a solar cell, in which a microstructured silicon substrate is subjected to AZO deposition to realize gap-filling, thereby reducing the reflectance thereof.

Another object of the present invention is to provide a method of manufacturing a silicon substrate for a solar cell, in which a microstructured silicon solar cell is subjected to AZO deposition through sputtering and irradiation with an e-beam, thereby improving the electrical properties thereof.

### Technical Solution

The present invention provides a silicon substrate for a solar cell, configured such that a silicon substrate having a microwire structure is deposited with AZO so as to gap-fill spaces between microwires with the AZO, and is irradiated with an e-beam.

Also, the silicon substrate may be configured such that a p-type silicon substrate is doped with an n-type dopant to form a p-n junction.

Also, the p-layer of the silicon substrate may be doped with aluminum to form an aluminum back-surface field (Al-BSF).

Also, the microwires of the silicon substrate may have a height of 0.5 to 1.0 μm, a width of 1.5 to 6 μm, and a spacing of 2 to 6 μm therebetween.

Also, the AZO may be deposited to a thickness of 0.2 to 1.0 μm.

Also, the e-beam may be applied at an intensity of 1 to 4 keV for a period of time ranging from 50 to 450 sec.

In addition, the present invention provides a method of manufacturing a silicon substrate for a solar cell, comprising: manufacturing a microstructured silicon substrate by forming microwires to protrude at a predetermined spacing on a flat base; gap-filling spaces between the microwires by depositing AZO on the microstructured silicon substrate; and irradiating the silicon substrate having the gap-filled microwires with an e-beam.

Also, the microwires of the microstructured silicon substrate may be formed using an etching process.

Also, the microstructured silicon substrate may be manufactured by forming a p-n junction of a p-type silicon substrate and an n-type silicon substrate.

Also, the p-layer of the microstructured silicon substrate may be doped with aluminum to form an aluminum back-surface field (Al-BSF).

Also, the microwires of the microstructured silicon substrate may have a height of 0.5 to 1.0 μm, a width of 1.5 to 6 μm, and a spacing of 2 to 6 μm therebetween.

Also, in the gap-filling the spaces between the microwires, the AZO may be deposited on the microstructured silicon substrate using any one process selected from among DC sputtering, RF sputtering, chemical vapor deposition, pulsed laser deposition, and activated reactive evaporation (ARE).

Also, in the gap-filling the spaces between the microwires, the AZO may be deposited to a thickness of 0.2 to 1.0 μm.

Also, the e-beam may be applied at an intensity of 1 to 4 keV for a period of time ranging from 50 to 450 sec.

### Advantageous Effects

According to the present invention, the silicon substrate for a solar cell is configured such that the spaces between microwires of the silicon substrate are gap-filled with AZO, thereby decreasing the reflectance of solar light.

Also, the silicon substrate, the microstructure of which is gap-filled with AZO, is irradiated with an e-beam, thereby altering the electrical properties thereof, in particular lowering the resistivity thereof.

Additionally, a solar cell having significantly improved electrical properties and a low price can be effectively manufactured using the silicon substrate having lowered reflectance and resistivity.

### DESCRIPTION OF DRAWINGS

FIG. 1 is a cross-sectional view illustrating a silicon substrate for a solar cell according to an embodiment of the present invention;

FIG. 2 is a flowchart illustrating the process of manufacturing a silicon substrate for a solar cell according to the present invention;

FIGS. 3 to 5 are scanning electron microscope (SEM) images illustrating silicon substrates having a microwire structure with a height of 0.7 μm, a width of 2 to 6 μm, and a spacing of 6 μm between microwires, after AZO deposition and e-beam irradiation at 2 KeV;

FIGS. 6 to 8 are SEM images illustrating silicon substrates having a microwire structure with a height of 0.7 μm, a width of 2 to 6 μm, and a spacing of 6 μm between microwires, after AZO deposition and e-beam irradiation at 3 KeV;

FIGS. 9 to 11 are graphs illustrating the results of measurement of a Hall effect depending on the irradiation time of an e-beam at 2 KeV in silicon substrates having a microwire structure with a height of 0.7 μm, a width of 2 to 6 μm, and a spacing of 6 μm between microwires;

FIGS. 12 to 14 are graphs illustrating the results of measurement of a Hall effect depending on the irradiation time of an e-beam at 3 KeV in silicon substrates having a microwire structure with a height of 0.7 μm, a width of 2 μm, and a spacing of 6 μm between microwires;

FIGS. 15 to 17 are graphs illustrating the reflectance of silicon substrates having a microwire structure with a height of 0.7 μm, a width of 2 to 6 μm, and a spacing of 6 μm between microwires, after e-beam irradiation at 2 KeV; and

FIGS. 18 to 20 are graphs illustrating the reflectance of silicon substrates having a microwire structure with a height of 0.7 μm, a width of 2 to 6 μm, and a spacing of 6 μm between microwires, after e-beam irradiation at 3 KeV.

### MODE FOR INVENTION

Hereinafter, a detailed description will be given of preferred embodiments of the present invention through the appended drawings. Throughout the drawings, the same reference numerals refer to the same or like elements or parts. In the following description of the present invention, detailed descriptions of known constructions and functions incorporated herein will be omitted when they may make the gist of the present invention unclear.

It will be understood that when a particular allowable error in manufacturing and materials is presented in meaning, the terms “about” and “substantially” are used to mean a numerical value or a proximate value to the numerical value. The terms are also used to help the understanding of the present invention and to prevent the unfair use of the disclosure mentioning an accurate or absolute numeral value.

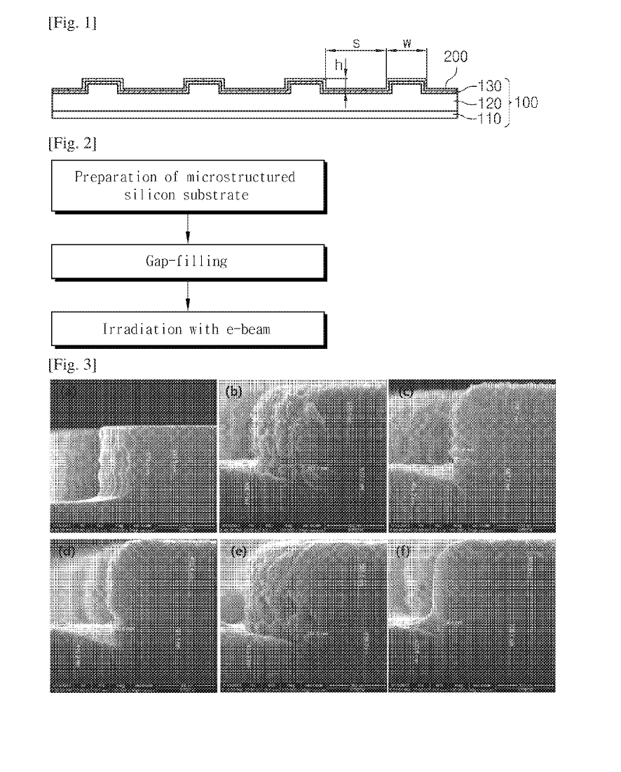

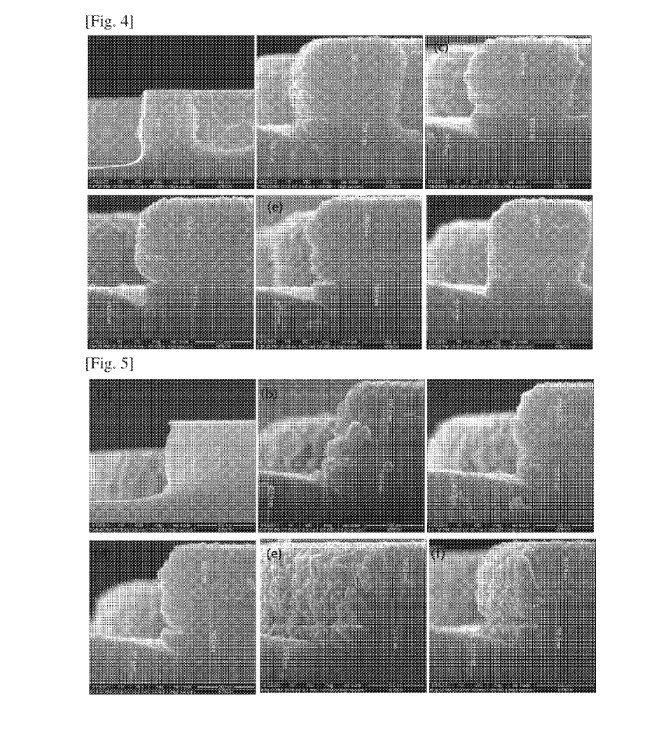

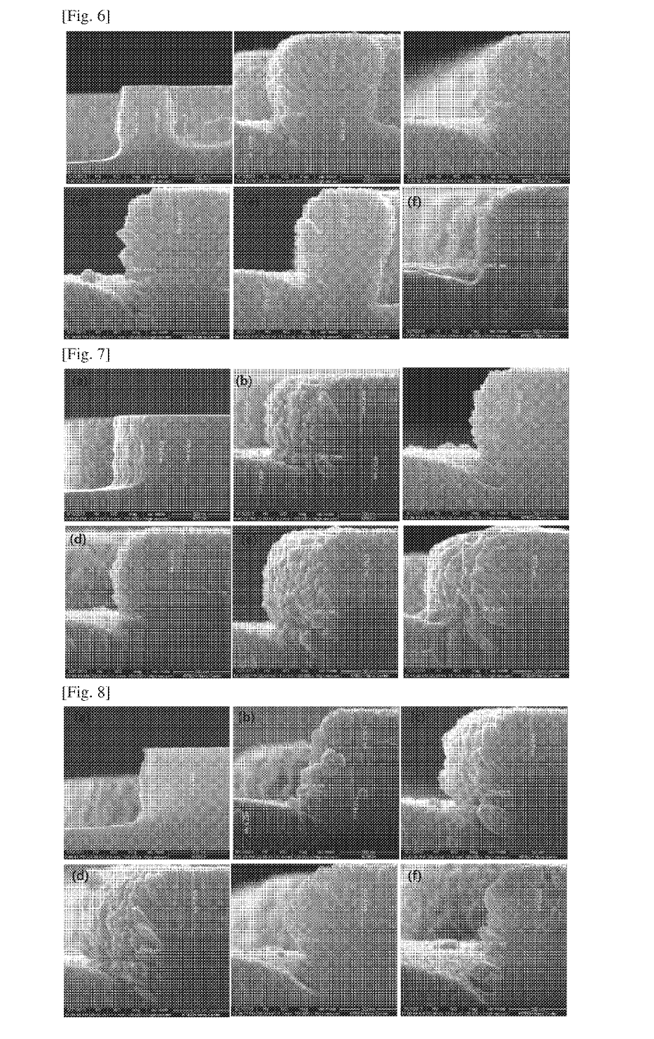

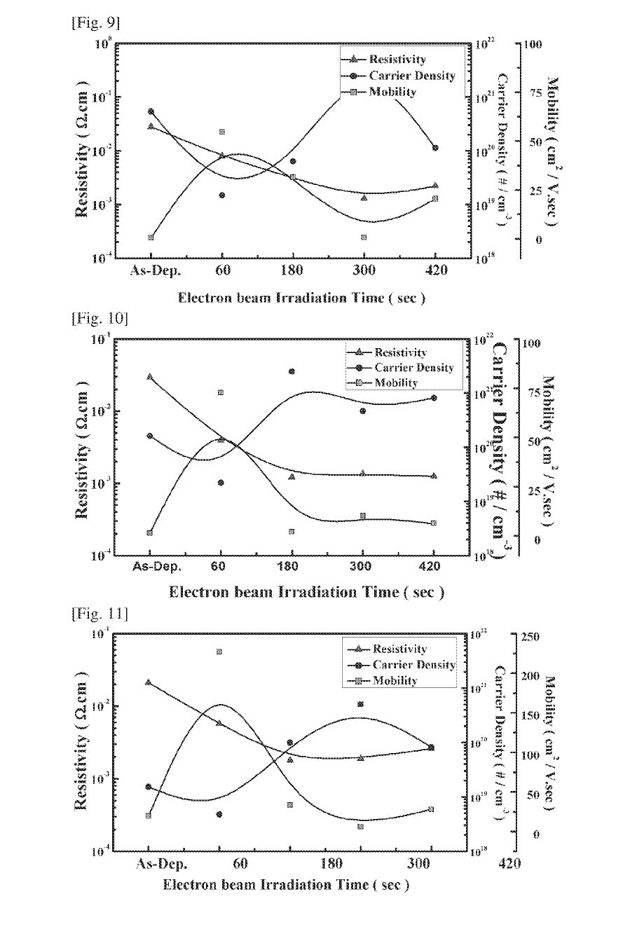

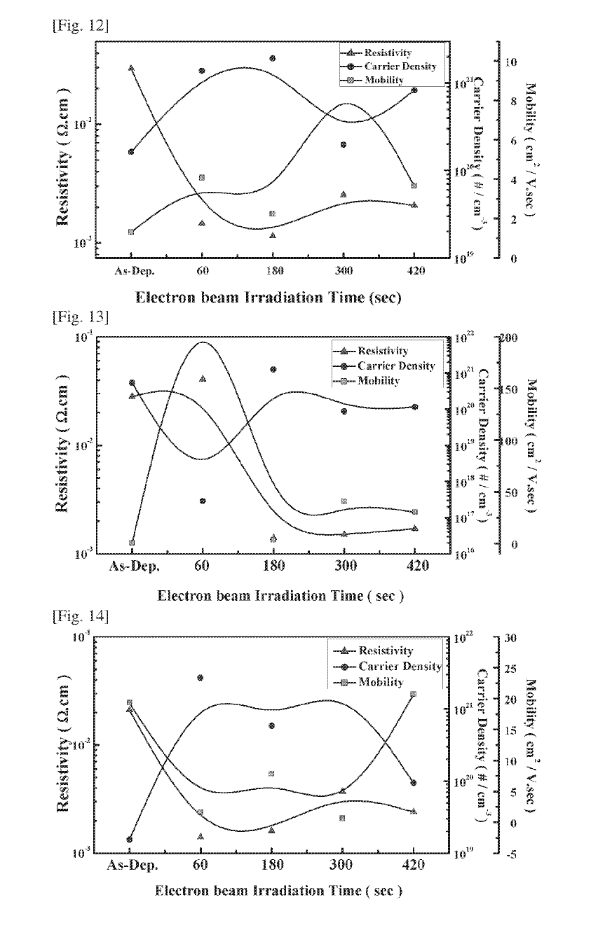

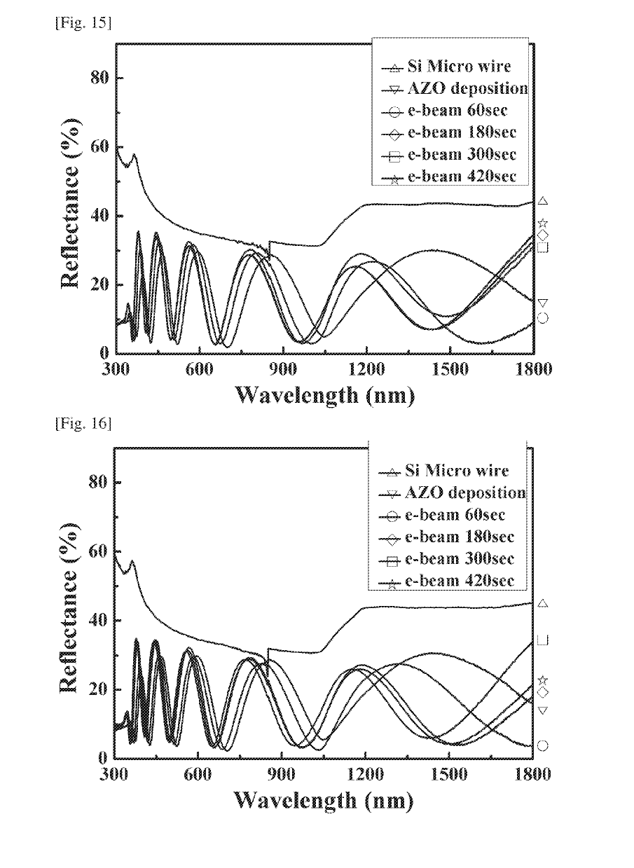

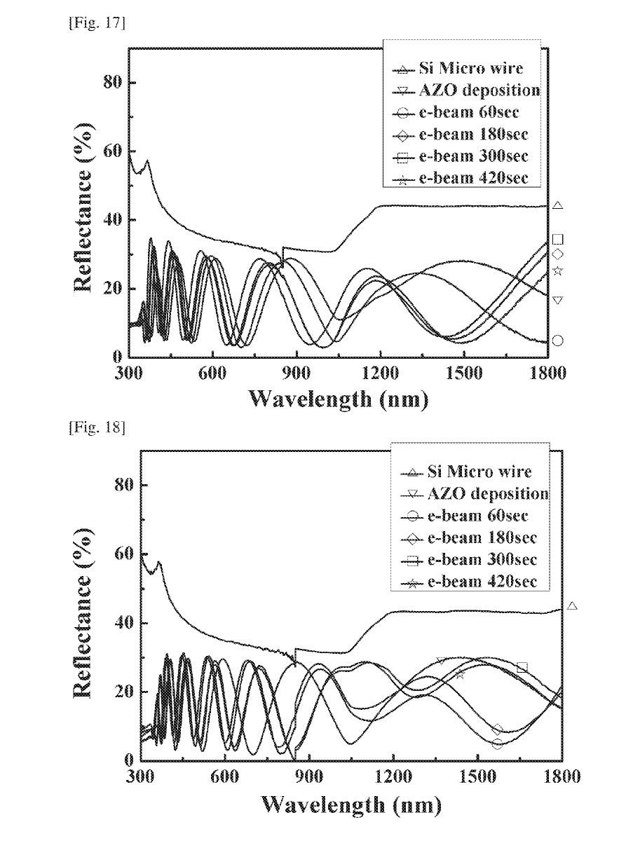

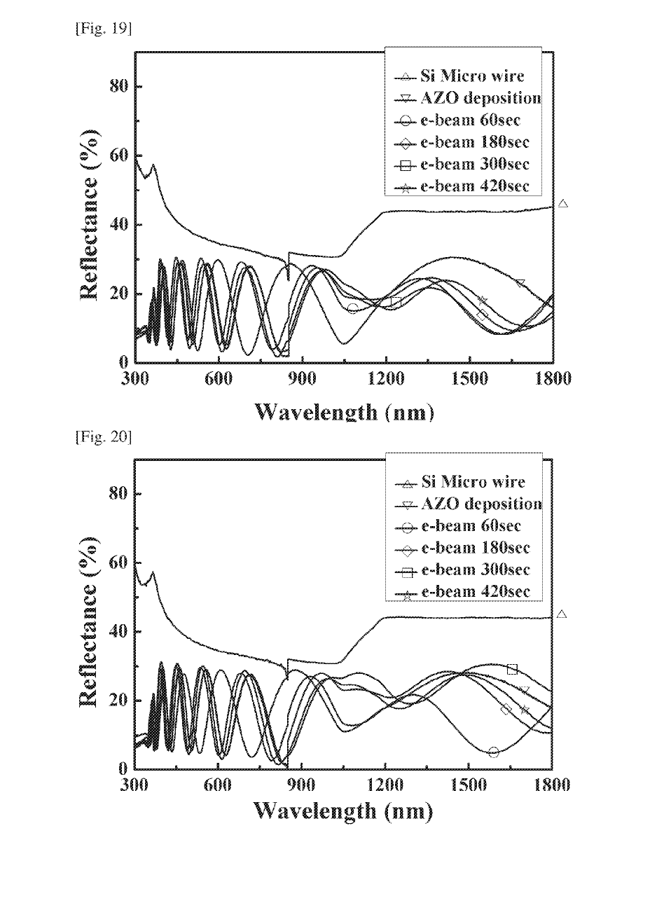

FIG. 1 is a cross-sectional view illustrating a silicon substrate for a solar cell according to an embodiment of the present invention, FIG. 2 is a flowchart illustrating the process of manufacturing a silicon substrate for a solar cell according to the present invention, FIGS. 3 to 5 are SEM images illustrating silicon substrates having a microwire structure with a height of 0.7 μm, a width of 2 to 6 μm, and a spacing of 6 μm between microwires, after AZO deposition and e-beam irradiation at 2 KeV, FIGS. 6 to 8 are SEM images illustrating silicon substrates having a microwire structure with a height of 0.7 μm, a width of 2 to 6 μm, and a spacing of 6 μm between microwires, after AZO deposition and e-beam irradiation at 3 KeV, FIGS. 9 to 11 are graphs illustrating the results of measurement of a Hall effect depending on the irradiation time of an e-beam at 2 KeV in silicon substrates having a microwire structure with a height of 0.7 μm, a width of 2 to 6 μm, and a spacing of 6 μm between microwires, FIGS. 12 to 14 are graphs illustrating the results of measurement of a Hall effect depending on the irradiation time of an e-beam at 3 KeV in silicon substrates having a microwire structure with a height of 0.7 μm, a width of 2 μm, and a spacing of 6 μm between microwires, FIGS. 15 to 17 are graphs illustrating the reflectance of silicon substrates having a microwire structure with a height of 0.7 μm, a width of 2 to 6 μm, and a spacing of 6 μm between microwires, after e-beam irradiation at 2 KeV, and FIGS. 18 to 20 are graphs illustrating the reflectance of silicon substrates having a microwire structure with a height of 0.7 μm, a width of 2 to 6 μm, and a spacing of 6 μm between microwires, after e-beam irradiation at 3 KeV.

n the silicon substrate having a microwire structure for a solar cell according to the present invention, the silicon substrate having a microwire structure is deposited with AZO so as to gap-fill the spaces between the microwires with AZO, and is irradiated with an e-beam.

As illustrated in FIG. 1, the silicon substrate 100 is configured such that a p-type silicon substrate 120 is doped with an n-type dopant 130 to form a p-n junction, and the silicon substrate 100 has microwires that are formed to protrude therefrom to thus enlarge the area where the p-n junction is formed, and the area may be further enlarged with an increase in the density and aspect ratio of the wires.

Furthermore, aluminum is doped on the back surface of the p-type silicon substrate 120, which is not doped with the n-type dopant 130 of the silicon substrate 100, thus forming an aluminum back-surface field (Al-BSF) 110. The formation of the Al-BSF 110 is a process for improving the efficiency of a silicon solar cell, and the back surface of the p-type silicon substrate of the silicon substrate for use in a solar cell is doped at a high concentration, thus generating a difference in potential and impeding the transfer of a small number of carriers to the back surface, thereby decreasing the rate of recombination on the back surface. Accordingly, the open voltage is increased and the fill factor may be increased.

The height (h of FIG. 1) of the microwires of the silicon substrate 100, the width (w of FIG. 1) thereof, and the spacing (s of FIG. 1) between the microwires are not particularly limited, so long as they fall within the micro-unit range. Preferably, the microwires have a height h of 0.5 to 1.0 μm, a width of 1.5 to 6 μm, and a spacing of 2 to 6 μm therebetween.

The AZO 200, which is deposed on the silicon substrate 100 to realize gap-filling, is a transparent conductive oxide (TCO). As for a silicon substrate for a solar cell in which AZO is deposited on a silicon substrate having no microwires, the produced electrons may be lost at the interface between the silicon substrate and the AZO. However, when the AZO 200 is deposited on the silicon substrate 100 having microwires according to the present invention, collection of the carriers produced by light may be increased. Furthermore, recombination of the carriers may be minimized compared to the silicon substrate having no microwires.

The AZO 200 is preferably deposited to a thickness of 0.2 to 1.0 μm.

The resistivity may be decreased by radiating an e-beam onto the silicon substrate having the AZO 200 deposited thereon. This is because the crystal size of the AZO 200 of the silicon substrate is increased through e-beam irradiation.

As illustrated in FIG. 2, the silicon substrate for a solar cell according to the present invention may be manufactured by forming a microstructured silicon substrate, configured such that microwires are formed to protrude at a predetermined spacing on a flat base, depositing AZO on the microstructured silicon substrate so that the spaces between the microwires are gap-filled therewith, and radiating an e-beam onto the silicon substrate in which the spaces between the microwires are gap-filled.

As illustrated in FIG. 3, the microstructured silicon substrate 100 may be manufactured by forming microwires using an etching process. The etching process may include any one selected from the group consisting of electrochemical etching, solution etching, and metal catalytic etching.

The microstructured silicon substrate 100 may be manufactured in a manner in which the p-n junction is formed and the Al-BSF 110 is formed on the back surface of the p-type silicon substrate 120, which is not doped with the n-type dopant 130. The height h, width w and spacing s of the microwires of the silicon substrate 100 are not particularly limited within the micro-unit range, but the microwires preferably have a height h of 0.5 to 1.0 μm, a width of 1.5 to 6 μm, and a spacing of 2 to 6 μm therebetween.

In the gap-filling step, AZO is deposited on the microstructured silicon substrate 100 using any one process selected from among DC sputtering, RF sputtering, chemical vapor deposition, pulsed laser deposition, and activated reactive evaporation (ARE). Particularly useful is DC sputtering or RF sputtering.

The AZO, which is deposited on the silicon substrate 100 to realize gap-filling, is preferably formed to a thickness of 0.2 to 1.0 μm, as mentioned above.

In the e-beam irradiation step, an e-beam is applied to increase the crystal size of the AZO 200 of the silicon substrate so as to decrease resistivity, as mentioned above, and the e-beam may be applied at an intensity of 1 to 4 keV, and preferably 2 keV, for a period of time ranging from 50 to 450 sec.

A better understanding of the present invention may be obtained through the following examples regarding the silicon substrate for a solar cell, which are set forth to illustrate, but are not to be construed to limit the present invention.

Manufacture of Silicon Substrate Having Microwire Structure for Solar Cell

Silicon substrates were manufactured in a manner in which microwires were formed through etching of a p-type silicon substrate so as to have a height h of about 0.7 μm, a spacing s of 6 μm therebetween and a width w of 2, 4, and 6 μm, and an n-type dopant was then doped thereon to form a p-n junction, after which the back surface of the p-type silicon substrate, which had not been doped with the n-type dopant of the silicon substrate, was doped with Al.

Deposited on the silicon substrate having microwires was AZO using sputtering.

### Example 1

The silicon substrates having microwires at a width w of 2, 4 and 6 μm, manufactured in the manufacture of the silicon substrate having a microwire structure as described above, were irradiated with an e-beam at a DC power of 2 keV for 60, 180, 300, and 420 sec.

In FIGS. 3 to 5, (a) shows the substrates before deposition of AZO in the manufacture of the silicon substrate having a microwire structure as above, (b) shows the substrates after the deposition of AZO but before e-beam irradiation, (c) shows the substrates after e-beam irradiation for 60 sec, (d) shows the substrates after e-beam irradiation for 180 sec, (e) shows the substrates after e-beam irradiation for 300 sec, and (f) shows the substrates after e-beam irradiation for 420 sec.

FIG. 3 illustrates SEM images of the silicon substrates having microwires with a height of 0.7 μm, a width of 2 μm, and a spacing of 6 μm therebetween, after deposition of AZO and e-beam irradiation at 2 KeV.

FIG. 4 illustrates SEM images of the silicon substrates having microwires with a height of 0.7 μm, a width of 4 μm, and a spacing of 6 μm therebetween, after deposition of AZO and e-beam irradiation at 2 KeV.

FIG. 5 illustrates SEM images of the silicon substrates having microwires with a height of 0.7 μm, a width of 6 μm, and a spacing of 6 μm therebetween, after deposition of AZO and e-beam irradiation at 2 KeV.

As illustrated in FIGS. 3 to 5, (a) shows the substrates before the deposition of AZO in the manufacture of the silicon substrate having a microwire structure as above, (b) shows the substrates after the deposition of AZO but before e-beam irradiation, (c) shows the substrates after e-beam irradiation for 60 sec, (d) shows the substrates after e-beam irradiation for 180 sec, (e) shows the substrates after e-beam irradiation for 300 sec, and (f) shows the substrates after e-beam irradiation for 420 sec.

### Example 2

The silicon substrates having microwires at a width w of 2, 4 and 6 μm, manufactured in the manufacture of the silicon substrate having a microwire structure as described above, were irradiated with an e-beam at a DC power of 3 keV for 60, 180, 300, or 420 sec.

In FIGS. 6 to 8, (a) shows the substrates before the deposition of AZO in the manufacture of the silicon substrate having a microwire structure as above, (b) shows the substrates after the deposition of AZO but before e-beam irradiation, (c) shows the substrates after e-beam irradiation for 60 sec, (d) shows the substrates after e-beam irradiation for 180 sec, (e) shows the substrates after e-beam irradiation for 300 sec, and (f) shows the substrates after e-beam irradiation for 420 sec.

FIG. 6 illustrates SEM images of the silicon substrates having microwires with a height of 0.7 μm, a width of 2 μm, and a spacing of 6 μm therebetween, after the deposition of AZO and e-beam irradiation at 3 KeV.

FIG. 7 illustrates SEM images of the silicon substrates having microwires with a height of 0.7 μm, a width of 4 μm, and a spacing of 6 μm therebetween, after the deposition of AZO and e-beam irradiation at 3 KeV.

FIG. 8 illustrates SEM images of the silicon substrates having microwires with a height of 0.7 μm, a width of 6 μm, and a spacing of 6 μm therebetween, after the deposition of AZO and e-beam irradiation at 3 KeV.

### Evaluation of Properties of Silicon Substrate

(1) Evaluation Method

The Hall effect is the production of an electromotive force in a direction orthogonal to current and a magnetic field when the magnetic field is applied perpendicular to the current, and represents the carrier density, mobility, and resistivity depending on the e-beam irradiation time.

(2) Results

FIGS. 9 to 11 are graphs illustrating the results of measurement of the Hall effect depending on the irradiation time of an e-beam at 2 keV in the silicon substrates having microwires with a height of 0.7 μm, a width of 2 to 6 μm and a spacing of 6 μm therebetween, in which FIGS. 9, 10 and 11 are graphs illustrating the results of measurement of the Hall effect when the width is 2 μm, 4 μm, and 6 μm, respectively.

FIGS. 12 to 14 are graphs illustrating the results of measurement of the Hall effect depending on the irradiation time of an e-beam at 3 keV in the silicon substrates having microwires with a height of 0.7 μm, a width of 2 to 6 μm and a spacing of 6 μm therebetween, in which FIGS. 12, 13 and 14 are graphs illustrating the results of measurement of the Hall effect when the width is 2 μm, 4 μm, and 6 μm, respectively.

As is apparent from the graphs, when the e-beam irradiation time was increased, resistivity was decreased, and was not further lowered due to saturation after the lapse of a predetermined period of time.

2. Spectrophotometry

(1) Evaluation Method

The maximum light absorption wavelength of the molecule is measured using a spectrophotometer, the reflectance is represented in units of %, and the average is obtained by averaging the reflective values of 300 to 1800 nm corresponding to the total wavelength range.

(2) Results

FIGS. 15 to 17 are graphs illustrating the reflectance of the silicon substrates having microwires with a height of 0.7 μm, a width of 2 to 6 μm and a spacing of 6 μm therebetween, after e-beam irradiation at 2 keV. Here, FIGS. 15, 16 and 17 are graphs illustrating the reflectance when the width is 2 μm, 4 μm, and 6 μm, respectively.

FIGS. 18 to 20 are graphs illustrating the reflectance of the silicon substrates having microwires with a height of 0.7 μm, a width of 2 to 6 μm and a spacing of 6 μm therebetween, after e-beam irradiation at 3 keV. Here, FIGS. 18, 19 and 20 are graphs illustrating the reflectance when the width is 2 μm, 4 μm, and 6 μm, respectively.

As is apparent from FIGS. 15 to 20, the substrate irradiated with an e-beam according to the present invention can exhibit very low reflectance of solar light compared to a substrate having no AZO deposited thereon.

1. A silicon substrate for a solar cell, configured such that a silicon substrate having a microwire structure is deposited with AZO (Al-doped ZnO) so as to gap-fill spaces between microwires with the AZO, and is irradiated with an e-beam.

2. The silicon substrate of claim 1, wherein the silicon substrate is configured such that a p-type silicon substrate is doped with an n-type dopant to form a p-n junction.

3. The silicon substrate of claim 1, wherein a p-layer of the silicon substrate is doped with aluminum to form an aluminum back-surface field (Al-BSF).

4. The silicon substrate of claim 1, wherein the microwires of the silicon substrate have a height of 0.5 to 1.0 μm, a width of 1.5 to 6 μm, and a spacing of 2 to 6 μm therebetween.

5. The silicon substrate of claim 1, wherein the AZO is deposited to a thickness of 0.2 to 1.0 μm.

6. A method of manufacturing a silicon substrate for a solar cell, comprising:
manufacturing a microstructured silicon substrate by forming microwires to protrude at a predetermined spacing on a flat base;
gap-filling spaces between the microwires by depositing AZO on the microstructured silicon substrate; and
irradiating the silicon substrate having the gap-filled microwires with an e-beam.

7. The method of claim 6, wherein the microwires of the microstructured silicon substrate are formed using an etching process.

8. The method of claim 6, wherein the microstructured silicon substrate is manufactured by forming a p-n junction of a p-type silicon substrate and an n-type silicon substrate.

9. The method of claim 6, wherein a p-layer of the microstructured silicon substrate is doped with aluminum to form an aluminum back-surface field (Al-BSF).

10. The method of claim 6, wherein the microwires of the microstructured silicon substrate have a height of 0.5 to 1.0 μm, a width of 1.5 to 6 μm, and a spacing of 2 to 6 μm therebetween.

11. The method of claim 6, wherein in the gap-filling the spaces between the microwires, the AZO is deposited on the microstructured silicon substrate using any one process selected from among DC sputtering, RF sputtering, chemical vapor deposition, pulsed laser deposition, and activated reactive evaporation (ARE).

12. The method of claim 6, wherein in the gap-filling the spaces between the microwires, the AZO is deposited to a thickness of 0.2 to 1.0 μm.

13. The method of claim 6, wherein the e-beam is applied at an intensity of 1 to 4 keV for a period of time ranging from 50 to 450 sec.
